(19) United States
(12) Patent Application Publication
(10) Pub. No.: US 2010/0171426 A1
(43) Pub. Date: Jul. 8, 2010

(54) HIGH-VOLTAGE PULSE GENERATOR AND HIGH-PRESSURE DISCHARGE LAMP HAVING SUCH A GENERATOR

(75) Inventors: Andreas Kloss, Neubiberg (DE); Bernhard Schalk, Eching (DE); Steffen Walter, Oberpframmern (DE)

Correspondence Address: Viering, Jentschura & Partner - OSR, 3770 Highland Ave., Suite 203, Manhattan Beach, CA, 90266, US

(73) Assignee: OSRAM GESELLSCHAFT MIT BESCHRAENKTER HAFTUNG, Muenchen (DE)

(21) Appl. No.: 12/601,856

(22) PCT Filed: May 26, 2008
(86) PCT No.: PCT/EP08/56414

§ 371 Date: Nov. 25, 2009

(30) Foreign Application Priority Data
May 29, 2007 (DE) 10 2007 024 890.5

(51) Int. Cl. H01J 7/44; H03K 3/02; H02K 15/00

(52) U.S. Cl. 315/56; 307/106; 29/596

(57) ABSTRACT

A high-voltage pulse generator is provided. The high-voltage pulse generator may include a spiral pulse generator, the spiral pulse generator being configured as an LTCC component and being wound from at least two ceramic sheets and at least two metal layers, wherein the two ceramic sheets are joined to form a multilayer structure including at least one first layer of a capacitively acting ceramic sheet including a high permittivity of at least ∈ᵣ=10 and at least one second layer of an inductively acting ceramic sheet having a high permeability of at least μᵣ=1.5, which are wound together with the metal layers to form a spiral.

### TECHNICAL FIELD

The invention relates to a high-voltage pulse generator according to the precharacterizing clause of claim 1. Such generators may in particular be used for high-pressure discharge lamps for general lighting or for photo-optical purposes or for automobiles. The invention furthermore relates to a high-pressure discharge lamp which is equipped with such a generator.

### PRIOR ART

The problem of igniting high-pressure discharge lamps is currently resolved by integrating the ignition apparatus into the ballast apparatus. A disadvantage of this is that the supply leads must be made high-voltage proof.

In the past, there have repeatedly been attempts to integrate the ignition unit into the lamp. In this context, attempts have been made to integrate it into the cap. Particularly effective ignition, offering high pulses, is achieved by means of high-voltage pulse generators of the spiral generator type. Some time ago, such apparatus were proposed for various high-pressure discharge lamps such as metal halide lamps or high-pressure sodium lamps, see for example U.S. Pat. No. 4,325,004 and U.S. Pat. No. 4,353,012. They were not however widely successful, because on the one hand they are too expensive. On the other hand, the advantage of building them into the cap is not sufficient, since the problem of feeding the high voltage into the bulb remains. The likelihood of damage to the lamp, whether insulation problems or breakdown in the cap, therefore increases greatly. Previously, it has not been possible to heat conventional ignition apparatus to more than 100° C. The voltage generated then has to be fed to the lamp, which requires supply leads and lamp fixtures with corresponding high-voltage strength, typically about 5 kV.

In conventional ignition circuits, a capacitor is normally discharged through a switch, for example a spark gap, into the primary winding of an ignition transformer. The desired high-voltage pulse is then induced in the secondary winding. In this context, see Sturm/Klein, Betriebsgerate and Schaltungen für elektrische Lampen [operating apparatus and circuits for electric lamps], p. 193 to 195 (6^{th} edition 1992).

FIG. 1b shows the layer structure of a conventional spiral pulse generator, as has been used previously. An active dielectric layer 50 is arranged between two metal layers 3 and 4. The layer consists of a capacitively acting material having a high ∈ᵣ. The voltage U₀ is applied between the two metal layers. Since this layer structure is wound, a further insulation layer is necessary. It consists of an inductive material 52 having a high permeability μᵣ. Since most inductive materials are not good insulators, however, and the voltage U₀ is likewise applied to the inductive layer, a leakage current through the inductive layer is formed as indicated by the arrows in FIG. 1b. This represents a considerable performance loss of the spiral pulse generator. The possible charging voltage of the spiral pulse generator is thereby greatly impaired.

### SUMMARY OF THE INVENTION

It is an object of the present invention to provide a high-voltage pulse generator, the impedance and pulse width of which can be selected as freely as possible in a wide range.

This object is achieved by the characterizing features of claim 1.

Particularly advantageous configurations may be found in the dependent claims.

It is also an object of the present invention to provide a compact high-pressure discharge lamp. This object is achieved by the characterizing features of claim 14.

It is another object to provide a method for producing such a compact spiral pulse generator.

This object is achieved by the characterizing features of claim 11.

According to the invention a high-voltage pulse of at least 1.5 kV, which is required for example in order to ignite a lamp, is generated by means of a special heat-resistant spiral pulse generator.

In particular, when used in a high-pressure discharge lamp, it can be integrated in the immediate vicinity of the discharge vessel in the outer bulb. This allows not only cold ignition but also hot reignition.

The spiral pulse generator now used is in particular a so-called LTCC component. This material is a special ceramic, which can be made thermally stable up to 600° C. LTCC has in fact already been used in connection with lamps, see US 2003/0001519 and U.S. Pat. No. 6,853,151. Nevertheless, it was used for very different purposes in lamps which experience scarcely any thermal stress, with typical temperatures lower than 100° C. The particular benefit of the high thermal stability of LTCC is to be found in connection with the ignition of high-pressure discharge lamps, such as above all metal halide lamps with ignition problems.

The spiral pulse generator is a component which combines properties of a capacitor with those of a waveguide in order to generate ignition pulses with a voltage of at least 1.5 kV. For production, two “unfired” ceramic sheets are printed on using conductive metal paste or laminated onto a metal foil and subsequently wound offset to form a spiral, and finally pressed isostatically to form a shaped body. The subsequent co-sintering of the metal paste/foil and ceramic sheet is carried out in air in the temperature range of between 800 and 900° C. This processing permits a working range of the spiral pulse generator up to a thermal stress of 700° C. The spiral pulse generator can therefore be fitted in the direct vicinity of the discharge vessel in the outer bulb, but also in the cap or in the immediate vicinity of the lamp.

Independently of this, such a spiral pulse generator may also be used for other applications because it is not only highly thermally stable but also extremely compact. To this end, it is essential for the spiral pulse generator to be configured as an LTCC component consisting of ceramic sheets and conductive metal paste, or a foil. In order to deliver a sufficient starting voltage, the spiral should include at least 5 turns.

In addition, on the basis of this high-pressure pulse generator, an ignition unit can be provided which furthermore includes at least one charging resistor and a switch. The switch may be a spark gap or a diac in SiC technology.

In the case of use for lamps, fitting in the outer bulb is preferred. This is because it obviates the need for a high-voltage proof voltage supply lead.

A spiral pulse generator can furthermore be dimensioned so that the high-voltage pulse even allows hot reignition of the lamp. The ceramic dielectric is distinguished by an extraordinarily high dielectric constant ∈ of ∈>10; depending on the material and the design, it is possible to achieve an ∈ of typically 70, up to ∈=10,000. This provides a very high capacitance of the spiral pulse generator and allows a comparatively large temporal width of the pulses generated. A very compact design of the spiral pulse generator is therefore possible, so that it can be incorporated into commercially available outer bulbs of high-pressure discharge lamps.

The large pulse width furthermore facilitates breakdown in the discharge volume.

Any conventional glass may be used as the material of the outer bulb, i.e. in particular hard glass, Vycor or quartz glass. The choice of fill is also not subject to any particular restriction.

From DE 10 2006 026 751 A1, it is already known that particularly easy adaptation of the desired properties of an LTCC spiral pulse generator is achieved by not simply using a material having a desired dielectric constant as the dielectric, but instead a mixture of two materials, of which a first material is a dielectric having a given ∈ᵣ and the second material a given μᵣ, i.e. a relative permeability. Although a single material having an ∈ᵣ of from 4 to 10,000 has previously been used, according to the teaching of DE 10 2006 026 751 A1 it is possible to use a mixture in which the first material can have an ∈ᵣ of from 2 to 10,000 while the second material is inductive and can have a μᵣ of from 1 to 5000. Preferably, μᵣ is as high as possible and is equal to at least 10, particularly preferably at least 100. Previously, the value of μᵣ in the known materials has been close to 1; adaptation was not possible. A proportion of from 5 to 35 wt % for the inductive material is proposed therein as a typical mixture.

It is however possible, and even advantageous over this, to adopt a different approach: because the poorly insulating inductive material is now enclosed in a three-layer structure, in each case by a layer of the highly insulating capacitive material, a good insulation strength is ensured overall since the highly insulating capacitive material insulates the conductive material.

The particular benefit of the new degree of freedom is the separate adaptation and adjustment of the dielectric and inductive properties of a spiral pulse generator, so that bespoke adjustment of the impedance of the spiral pulse generator and the pulse width of the high-voltage pulse generated is possible. In principle, the importance of the separate adjustability may be seen from the following consideration:

For adaptation of the pulse width, characteristic impedance and pulse energy of a spiral pulse generator, μ and ∈ should be selected according to the following guideline: the characteristic impedance Z₀ of a spiral pulse generator is given by

$${Z}_{0} \sim \sqrt{\frac{{μ}_{0} \cdot {μ}_{r}}{{ɛ}_{0} \cdot {ɛ}_{r}}} ,$$

with μ₀—permeability of free space, and ∈₀—permittivity of free space, μᵣ—relative permeability, and ∈ᵣ-relative dielectric constant. The energy of the pulse generated is proportional to ∈ᵣ. The pulse width of the spiral pulse generator is given by τ˜\sqrt{μ₀·μᵣ·∈₀·∈ᵣ}. For efficient functionality of the generator, L_{S}<<(Z₀·τ) must apply with Lₛ—inductance of the short-circuit switch. Because Z₀·τ˜μᵣ, this adaptation to the inductance of the short-circuit switch can be achieved through selection of the relative permeability.

Spiral pulse generators are generally constructed from two layers of a conductor and an insulator, respectively configured as spirals. Details of this may be found particularly in DE 10 2005 061 832 A1. The two nonconductive layers in this case consist of the same material. Through selection of this material, it is possible to adjust definitively the permeability μ and the permittivity ∈ which in the end determine the properties of the spiral pulse generator. Essential properties are the impedance L of the waveguide, with Z˜√(μ/∈), or rise time τ of the pulse generated, with τ˜1/(μ*∈).

Owing to predetermined material properties, insulating layers simultaneously having high values of μ and ∈ as proposed in the prior art are available only limitedly and not in a freely selectable way. The use of a mixed ferrite is difficult to implement. Another possibility, which is explained in DE 10 2006 026 750 A1, is to use a uniform homogeneous material as a good insulator with a given high ∈, and subsequent encapsulation of the spiral pulse generator with inductive material having a high permeability μ. This encapsulation technique does however require a material with an extraordinarily high μ, which by reciprocity allows high-temperature application only to a very limited extent owing to the low Curie temperature of such a material. Furthermore, encapsulating the entire spiral pulse generator afterwards is very volume-intensive and therefore unfavorable.

In order to provide freely selectable parameterization of the properties, a spiral pulse generator is constructed so that different materials or a multilayer structure are used for the active layer and for the passive layer.

In a first embodiment, the active and passive layers have different properties. It is primarily the permittivity ∈ which is responsible for the properties of the active layer of a spiral pulse generator which is constructed from ceramic sheets, while the permeability μ is determined by the passive layer.

In a second embodiment, the active and passive layers consist of a multilayer structure. In this case, the active layer of the spiral pulse generator is constructed from 3 ceramic layers: a layer of conductive material is enclosed by two layers of capacitive material. If the spiral pulse generator is constructed so that the capacitive layer has a high ∈ᵣ of at least 10, preferably in the range of ∈ᵣ=10 to 10,000, while the inductive layer uses a different material which is distinguished by a high permeability with μᵣ=1 to 5000, preferably μᵣ>2, then the material properties respectively available individually can be used in combination in order to ensure the freest possible parameterization of the properties. Such a structure has very low losses, since the capacitive material is highly insulating. It is therefore also possible to use inductive material having a medium permeability μᵣ and at the same time a high Curie temperature.

A titanate such as BaTiO₃ or (Ba,Sr)TiO₃ is preferably suitable as a material for the capacitive layer. In particular a ferrite, such as an Mn/Zn ferrite, is suitable as a material for the inductive layer.

### BRIEF DESCRIPTION OF THE DRAWINGS

The invention will be explained in more detail below with the aid of several exemplary embodiments. In the figures:

FIG. 1a shows a conventional spiral pulse generator according to the active-passive concept;

FIG. 1b shows the schematic structure of the layer sequence of a conventional spiral pulse generator according to the active-passive concept;

FIG. 2 shows the characteristics of an LTCC spiral pulse generator;

FIG. 3a shows the schematic structure of the layer sequence of a spiral pulse generator according to the invention, having a three-layer structure between the metal layers;

FIG. 3b shows the schematic structure of the layers after the production method according to the invention;

FIG. 4 shows the circuit diagram of a high-pressure sodium lamp having a spiral pulse generator in the outer bulb;

FIG. 5 shows the circuit diagram of a metal halide lamp having a spiral pulse generator in the outer bulb;

FIG. 6 shows a metal halide lamp having a spiral pulse generator in the outer bulb;

FIG. 7 shows a metal halide lamp having a spiral pulse generator in the cap.

### PREFERRED EMBODIMENT OF THE INVENTION

A conventional spiral pulse generator is either wound from two ceramic sheets coated with metal paste or constructed from two metal foils and two ceramic sheets. An important characteristic in this case is the number n of turns, which should preferably be of the order of from 5 to 100. This arrangement of turns is then laminated and subsequently sintered, so as to create an LTCC component. The spiral pulse generators with a capacitor property, which are obtained in this way, are then connected to a spark gap and a charging resistor. The spark gap functions as a high-voltage switch, which initiates the pulse. The ceramic sheet is in this case a mixture of dielectric material with ∈ᵣ between 2 and 10,000, and inductive material with μᵣ between 1.5 and 5000.

The spark gap may be located on the inner or outer terminals, or inside the winding of the generator. It is also possible to use a semiconductor switch based on SiC, for example a MESFET from Cree. One of these is very thermally stable and suitable for temperatures above 350° C.

In a specific exemplary embodiment, a ceramic material with E=60 to 70 is used. A ceramic sheet, in particular a ceramic tape such as Heratape CT 707 or preferably CT 765, or a mixture of the two, both from Heraeus, is preferably used as the dielectric. It has an unfired sheet thickness typically from 50 to 150 μm. In particular Ag conductive paste, such as “Cofirable Silver”, likewise from Heraeus, is used as the conductor. A specific example is CT 700 from Heraeus. Good results are also delivered by the metal paste 6142 from DuPont. These parts can be laminated well and then heated (“burnout”) and sintered together (“co-firing”).

The inner diameter ID of the spiral pulse generator is 10 mm. The width of the individual strips is likewise 10 mm. The sheet thickness is 50 μm and the outer thicknesses of the two conductors are also 50 μm each. The charging voltage is 300 V. Under these conditions, the spiral pulse generator achieves an optimum in its properties with a turns number of n=20 to 70.

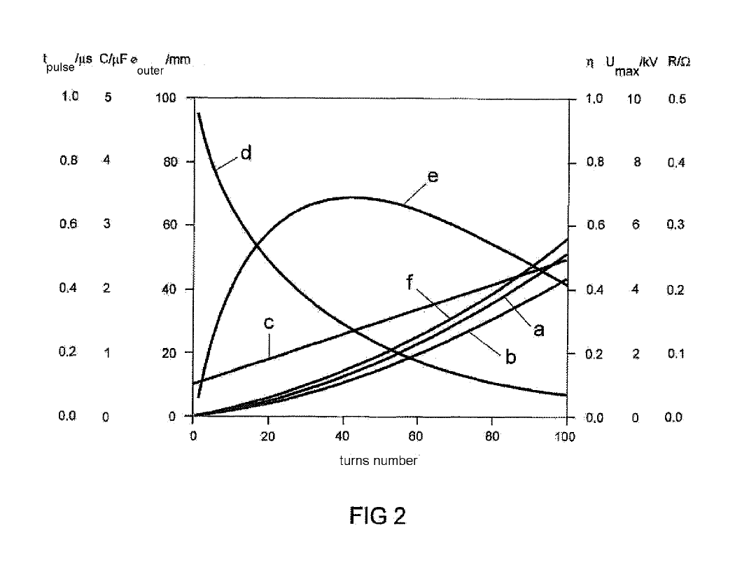

FIG. 2 shows the associated width at half maximum of the high-voltage pulse in μs (curve a), the total capacitance of the component in μF (curve b), the resulting outer diameter in mm (curve c), as well as the efficiency (curve d), the maximum pulse voltage (curve e) in kV and the conductor resistance in Ω (curve f).

### First Embodiment

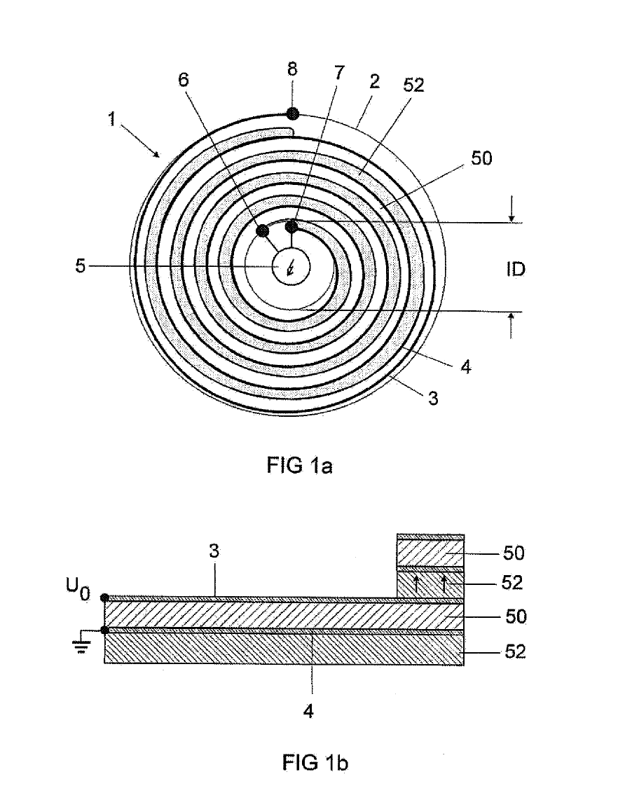

FIG. 1a shows the structure of the first embodiment of a spiral pulse generator 1 in plan view. It consists of a ceramic cylinder 2, in which two different metal conductors 3 and 4 are wound spirally as a foil composite. The cylinder 2 is internally hollow and has a given internal diameter ID. The two inner contacts 6 and 7 of the two conductors 3 and 4 preferably lie next to one another and are connected together via a spark gap 5. Between the two metal conductors lie the two ceramic sheets, which respectively are used as insulators and are made from different materials. One sheet 50 is made of material with a high ∈, in particular BaTiO₃. This sheet acts as the active layer in the spiral pulse generator. The second sheet 52 is made of a material with a high p, in particular Mn/Zn ferrite. This sheet acts as the passive layer in the spiral pulse generator. The active layer in the winding of the spiral pulse generator is preferably the one which is short-circuited via the contacts 6 and 7 lying next to one another.

Only the outer of the two conductors has a further contact 8 on the outer edge of the cylinder. The other conductor ends open. The two conductors therefore together form a waveguide in a dielectric material, the ceramic.

In an alternative structure, the two contacts for the short-circuit switch lie externally on the ring and the single contact internally.

FIG. 1b shows the layer structure of this spiral pulse generator, as has been used previously. An active dielectric layer 50 is arranged between two metal layers 3 and 4. The layer consists of a capacitively acting material with a high ∈ᵣ. The voltage U₀ is applied between the two metal layers. Since this layer structure is wound, a further insulation layer is required. It consists of an inductive material 52 with a high permeability μᵣ. Since most inductive materials are not good insulators, however, and the voltage U₀ is likewise applied to the inductive layer, a leakage current through the inductive layer is formed as indicated by the arrows in FIG. 1b. This represents a considerable performance loss of the spiral pulse generator. The possible charging voltage of the spiral pulse generator is thereby greatly impaired.

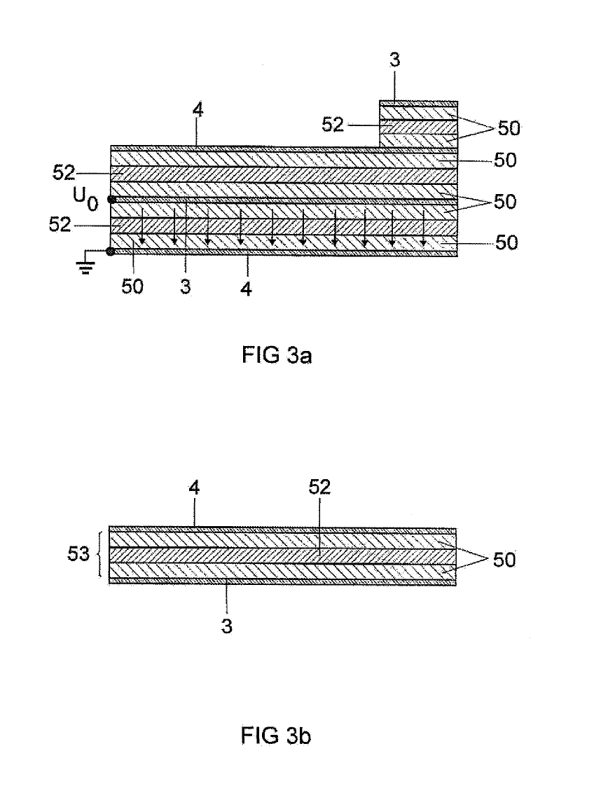

FIG. 3a shows the schematic structure of a spiral pulse generator according to the invention in development. A layer including three levels is arranged between the two metal layers 3 and 4, between which the voltage U₀ is applied. One level of conductive material 52 is in this case enclosed by two levels of capacitive material 50. This leads to good electrical insulation of the material 52 from the conductive metal layers 3 and 4, so that a problematic leakage current can reliably be prevented. The layers 50a and 52a show the layers actually lying closest together, as they would follow one another in a turn.

The three ceramic layers 53, which are shown in FIG. 3b, are built up by a tape casting method. First, the capacitively acting ceramic layer 50 with a high permittivity is cast onto a support sheet. The ceramic contained in this slurry may for example be BaTiO₃ or BaSrTiO₃, or another suitable capacitively acting ceramic. After this layer has dried, an inductively acting ceramic layer 52 is cast in a second step. A member of the material systems including Ba hexaferrite, NiZnCu ferrite or an MnZn ferrite with a high permeability may be contained in a slurry. This layer is subsequently also dried. In a third step, the layer system of the first layer 50 is finally cast once again by means of the tape casting method onto the inductively acting second layer 52. This creates a three-layer system, in which the ferrite layer with a high permeability is embedded between two layers with a high permittivity. The flow of electrical current when a voltage is applied through the ferrite layer will now be prevented by the permittive layers, since they act as insulation layers with a high capacitance.

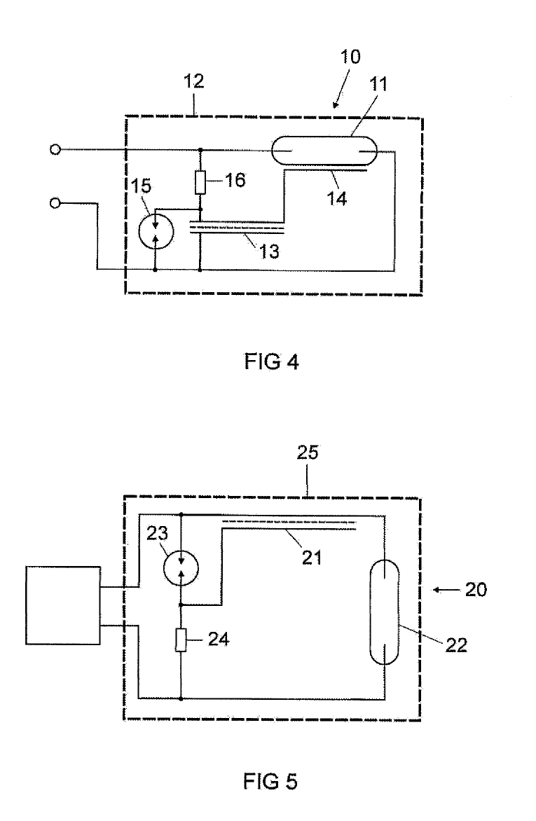

FIG. 4 shows the circuit diagram of a high-pressure sodium lamp 10 having a ceramic discharge vessel 11 and an outer bulb with a spiral pulse generator 13 integrated in it, an ignition electrode 14 being applied externally on the ceramic discharge vessel 11. The spiral pulse generator 13 is fitted with the spark gap 15 and the charging resistor 16 in the outer bulb.

FIG. 5 shows the circuit diagram of a metal halide lamp 20 having an integrated spiral pulse generator 21, without an ignition electrode being externally applied on the discharge vessel 22, which may be made of quartz glass or ceramic. The spiral pulse generator 21 is fitted with the spark gap 15 and the charging resistor 24 in the outer bulb 25.

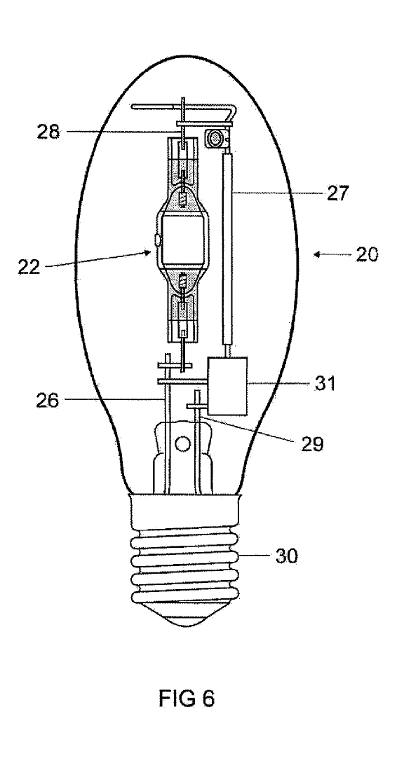

FIG. 6 shows a metal halide lamp 20 having a discharge vessel 22, which is held in an outer bulb by two supply leads 26, 27. The first supply lead 26 is a shortly angled-off wire. The second 27 is essentially a rod, which leads to the feed-through 28 on the opposite side from the cap. Between the supply lead from the cap 30 and the rod 27, an ignition unit 31 is arranged which contains the spiral pulse generator, the spark gap and the charging resistor, as indicated in FIG. 4.

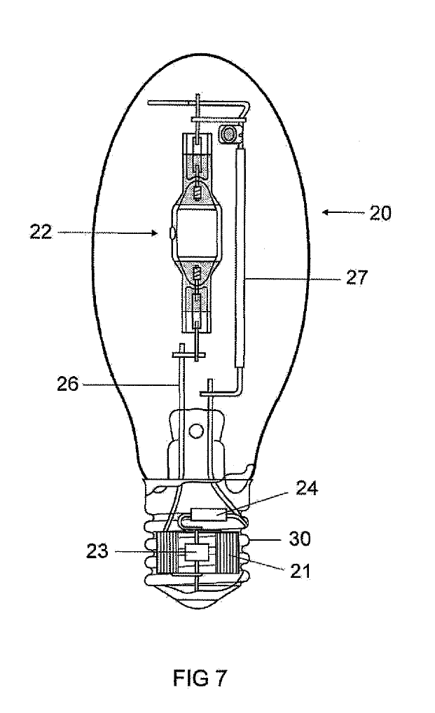

FIG. 7 shows a metal halide lamp 20 similarly as FIG. 3, having a discharge vessel 22 which is held in an outer bulb 25 by two supply leads 26, 27. The first supply lead 26 is a shortly angled-off wire. The second 27 is essentially a rod, which leads to the feed-through 28 on the opposite side from the cap. Here the ignition unit is arranged in the cap 30, and specifically both the spiral pulse generator 21 and the spark gap 23 and the charging resistor 24.

This technique may also be employed for electrodeless lamps, in which case the spiral pulse generator may be used as an ignition aid.

Further applications of this compact high-voltage pulse generator may be found in the ignition of other apparatus. Its use is advantageous above all for so-called magic spheres, for the generation of X-ray pulses and for the generation of electron-beam pulses. It may also be used in motor vehicles as a replacement for the conventional ignition coils.

Turns numbers n of up to 500 are used, so that the output voltage reaches the order of 100 kV. Specifically, the output voltage U_{A} is given as a function of the charging voltage U_{L} by U_{A}=2×n×U_{L}×η, the efficiency η being given by η=(AD−ID)/AD.

The invention offers particular advantages in conjunction with high-pressure discharge lamps for automobile headlamps which are filled with xenon at a high pressure of preferably at least 3 bar and metal halides. These are particularly difficult to ignite since the ignition voltage is more than 10 kV owing to the high xenon pressure. Currently, the components of the ignition unit are fitted in the cap. A spiral pulse generator having an integrated charging resistor may be fitted either in the cap of the automobile lamp or in an outer bulb of the lamp.

The invention offers very particular advantages in conjunction with high-pressure discharge lamps which do not contain mercury. Such lamps are particularly desirable for environmental protection reasons. They contain a suitable metal halide fill and, in particular, a noble gas such as xenon at a high pressure. Owing to the absence of mercury, the ignition voltage is particularly high. It is more than 20 kV. Currently, the components of the ignition unit are fitted in the cap. A spiral pulse generator having an integrated charging resistor may be fitted either in the cap of the mercury-free lamp or in an outer bulb of the lamp.

Besides Mn—Zn ferrite, other known ferrites are also suitable in principle for the passive layer, for example iron oxides. The relative permeability μᵣ should be at least 1.5. As a general rule, μᵣ will be selected at from 4 to 15,000. In particular, iron oxide with doping is suitable. For example, Mg or Al may be envisaged as a dopant. Other suitable metal oxides are those of nickel, manganese, magnesium, zinc and cobalt, individually or as a mixture, in particular Ni—Zn. In this case, the permeability is often to be selected at least at μᵣ=10.

1. A high-voltage pulse generator, comprising: a spiral pulse generator, the spiral pulse generator being configured as an LTCC component and being wound from at least two ceramic sheets and at least two metal layers, wherein the two ceramic sheets are joined to form a multilayer structure comprising at least one first layer of a capacitively acting ceramic sheet comprising a high permittivity of at least ∈ᵣ=10 and at least one second layer of an inductively acting ceramic sheet comprising a high permeability of at least μᵣ=1.5, which are wound together with the metal layers to form a spiral.

2. The high-voltage pulse generator as claimed in claim 1, wherein the multilayer structure of the ceramic sheets is located between the metal layers of the spiral pulse generator.

3. The high-voltage pulse generator as claimed in claim 1, wherein the at least one inductively acting ceramic sheet is insulated from at least one metal layer by the at least one capacitively acting ceramic sheet.

4. The high-voltage pulse generator as claimed in claim 3, wherein the at least one inductively acting ceramic sheet is insulated from two metal layers on each side by at least one capacitively acting ceramic sheet.

5. The high-voltage pulse generator as claimed in claim 1, wherein at least one metal layer is produced from a conductive metal paste.

6. The high-voltage pulse generator as claimed in claim 1, wherein at least one metal layer is produced from a metal foil.

7. The high-voltage pulse generator as claimed in claim 1, wherein the spiral comprises at least n=5.

8. The high-voltage pulse generator as claimed in claim 1, wherein the inductively acting sheet is produced predominantly from titanate.

9. The high-voltage pulse generator as claimed in claim 1, wherein the inductively acting sheet is produced predominantly from Mn—Zn ferrite material.

10. The high-voltage pulse generator as claimed in claim 1, wherein together with a charging unit and together with a short-circuit switch it forms an ignition unit.

11. A method for producing a ceramic spiral pulse generator, the spiral pulse generator being configured as an LTCC component and being wound from at least two ceramic sheets and at least two metal layers, wherein the two ceramic sheets are joined to form a multilayer structure comprising at least one first layer of a capacitively acting ceramic sheet comprising a high permittivity of at least ∈ᵣ=10 and at least one second layer of an inductively acting ceramic sheet comprising a high permeability of at least μᵣ=1.5, which are wound together with the metal layers to form a spiral;
the method comprising:
applying an unfired capacitively acting ceramic sheet onto a support sheet;
applying an unfired inductively acting ceramic sheet onto the capacitively acting unfired ceramic sheet;
applying a further unfired capacitively acting ceramic sheet onto the unfired inductively acting ceramic sheet, so as to create a sheet composite;
drying the sheet composite comprising the unfired sheets, and optionally removing the support sheet;
winding an unfired body from two superimposed sheet composites;
laminating the spirally wound unfired body; and
sintering the unfired laminated spiral body so as to create a spiral pulse generator.

12. The method for producing a ceramic spiral pulse generator as claimed in claim 11, wherein the support sheet provided is a metal foil.

13. The method for producing a ceramic spiral pulse generator as claimed in claim 11, wherein after the support sheet is removed from the unfired sheet composite, the latter is laminated onto a metal foil, the metal foil being used as a metal support.

14. A high-pressure discharge lamp having a discharge vessel which is fitted in an outer bulb, the lamp comprising an integrated ignition device which generates high-voltage pulses in the lamp and the ignition device being fitted in the outer bulb of the high-pressure discharge lamp, wherein the ignition device is a spiral pulse generator being configured as an LTCC component and being wound from at least two ceramic sheets and at least two metal layers, wherein the two ceramic sheets are joined to form a multilayer structure comprising at least one first layer of a capacitively acting ceramic sheet comprising a high permittivity of at least ∈ᵣ=10 and at least one second layer of an inductively acting ceramic sheet comprising a high permeability of at least μᵣ=1.5, which are wound together with the metal layers to form a spiral, the at least two ceramic sheets being located between the two metal layers and the at least one inductively acting ceramic sheet being insulated by the at least one capacitively acting ceramic sheet.

15. The high-pressure discharge lamp as claimed in claim 14, further comprising:
a frame;
wherein the ignition device is held by the frame.

16. The high-pressure discharge lamp as claimed in claim 14, wherein the relative permeability of the material of the inductively acting sheet is at least μᵣ=1.5.

17. The high-pressure discharge lamp as claimed in claim 16, wherein the material of the inductively acting sheet is a metal oxide.

18. The high-pressure discharge lamp as claimed in claim 14, wherein the high voltage imparted by the spiral pulse generator acts directly on two electrodes in the discharge vessel.

19. The high-pressure discharge lamp as claimed in claim 14, wherein the high voltage imparted by the spiral pulse generator acts on an auxiliary ignition electrode fitted externally on the discharge vessel.

20. The high-pressure discharge lamp as claimed in claim 14, wherein the spiral pulse generator is constructed from a plurality of turns, the number n of turns being at least n=5.

21. The high-pressure discharge lamp as claimed in claim 20, wherein the number n of turns is at most n=500.

22. The high-pressure discharge lamp as claimed in claim 14, wherein the spiral pulse generator has an approximately hollow cylindrical shape with an inner diameter of at least 10 mm.

23. The high-pressure discharge lamp as claimed in claim 14, wherein a ballast resistor, which limits the charging current of the spiral pulse generator, is furthermore fitted in the outer bulb.

24. The high-pressure discharge lamp as claimed in claim 14, wherein the spiral pulse generator is made from an LTCC material.

25. The high-voltage pulse generator as claimed in claim 7, wherein the spiral comprises at most n=500 turns.

26. The method for producing a ceramic spiral pulse generator as claimed in claim 11, further comprising:
applying a metal layer onto the sheet composite.

27. The high-pressure discharge lamp as claimed in claim 17,
wherein the material of the inductively acting sheet is a metal oxide having a ceramic mixture content of at least 15 wt %.

28. The high-pressure discharge lamp as claimed in claim 21, wherein the number n of turns is at most n=100.
